(19) United States
(12) Patent Application Publication
(10) Pub. No.: US 2007/0148901 A1
(43) Pub. Date: Jun. 28, 2007

(54) METHOD FOR MANUFACTURING A SEMICONDUCTOR DEVICE

(76) Inventor: Jin-Hwan Kim, Seoul (KR)

Correspondence Address: SHERR & NOURSE, PLLC, 620 HERNDON PARKWAY, SUITE 200, HERNDON, VA, 20170, US

(21) Appl. No.: 11/613,052

(22) Filed: Dec. 19, 2006

(30) Foreign Application Priority Data
Dec. 27, 2005 (KR) 10-2005-0130811

(51) Int. Cl. H01L 21/76

(52) U.S. Cl. 438/400

(57) ABSTRACT

A method of manufacturing a semiconductor device includes the steps of forming a nitride film over a semiconductor substrate, forming at least one trench in the semiconductor substrate and forming an insulation film over the nitride film and in said at least one trench. The method further comprises the steps of forming a mask pattern over said at least one trench and selectively removing the insulation film using the mask pattern as a mask.

The present application claims priority under 35 U.S.C. 119 and 35 U.S.C. 365 to Korean Patent Application No. 10-2005-0130811 (filed on Dec. 27, 2005), which is hereby incorporated by reference in its entirety.

### BACKGROUND

Recently, high speed and large scale integration of semiconductor devices has rapidly progressed together with other improvements in semiconductor technology. The push for devices with a smaller critical dimension (CD) has increased in accordance with the miniaturization of patterns.

Demand for miniaturization is applied not only to patterns formed within a device region but also to a relatively wide device isolation film. This is because a reduction in the width of a device isolation well would save space for the device region.

Device isolation films may be formed through a local oxidation of silicon process (LOCOS). Device isolation films formed by LOCOS have a region resembling a bird's-beak produced at an edge portion thereof, which has two disadvantages. The bird's-beak region generates a leakage current, and it enlarges the area of the device isolation film.

A shallow trench isolation (STI) process uses a narrow device isolation film having a superior device isolation characteristic. A device isolation film may be formed using an STI process by: sequentially forming a nitride film and a photoresist over a semiconductor substrate, patterning the nitride film using the photoresist as a mask, etching the semiconductor substrate using the patterned nitride film as a mask so as to form trenches, forming a high density plasma (HDP) oxidation over the trenches and the nitride film, performing a chemical mechanical polishing (CMP) process on a surface of the HDP oxidation such that the nitride film is exposed, and finally removing the nitride film.

However, CMP process may not completely remove the HDP oxidation over the nitride film. Therefore, the process time for removing the nitride film becomes longer, and the HDP oxidation filling the trenches is gradually etched, so that the height of the device isolation film may be lower than that of the semiconductor substrate.

If the height of the device isolation film is lower than that of the semiconductor substrate as describe above, a semiconductor device may suffer a higher leakage current, so that the electrical characteristics and reliability of the device is degraded. Accordingly, the yield of products may be reduced.

### SUMMARY

Embodiments relate to a method of manufacturing a semiconductor device, wherein an isolation film is prevented from being formed at a lower height than that of a semiconductor substrate such that the characteristics and reliability of the semiconductor device can be enhanced.

In accordance embodiments, there is provided a method of manufacturing a semiconductor device, comprising the steps of: forming a nitride film over a semiconductor substrate with no device isolation film formed thereon; forming trenches by etching the semiconductor substrate using the nitride film as a mask; forming an insulation film over the entire surface of the semiconductor substrate; planarizing the insulation film; forming device isolation patterns on the insulation film in the trenches; removing the insulation film over the nitride film using the device isolation patterns as a mask; removing the device isolation patterns; and forming a device isolation film by removing the nitride film.

The planarizing may be performed through a chemical mechanical polishing (CMP) process. The device isolation patterns may be formed of a photoresist, and removing the insulation film may be performed through a wet etching process. The insulation film may be formed of a high density plasma oxidation.

### BRIEF DESCRIPTION OF THE DRAWINGS

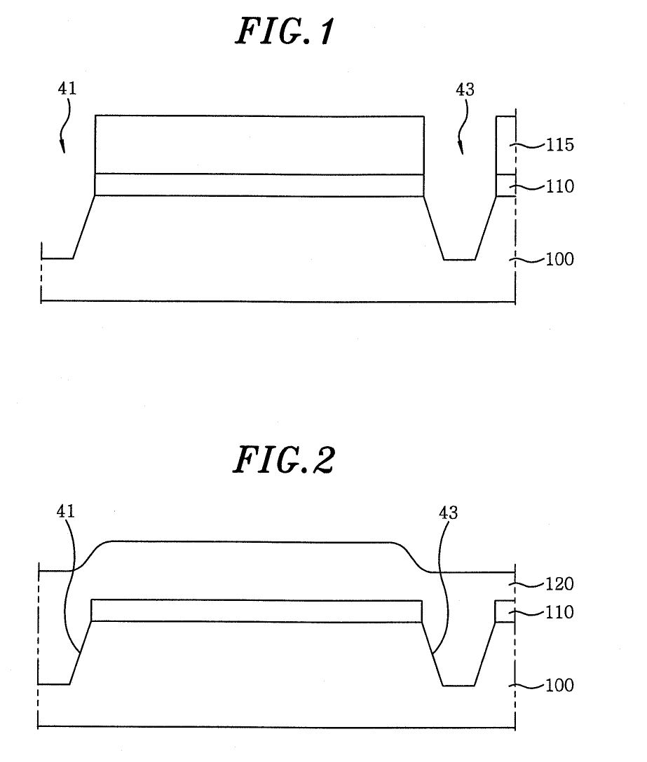

Example FIGS. 1 to 5 are sectional views illustrating a process of manufacturing a semiconductor device according to embodiments.

### DETAILED DESCRIPTION

In the drawings, the thickness of layers and regions are depicted in a magnified form for clarity, and like reference numerals are used to designate like elements throughout the specification and the drawings. Further, an expression that an element such as a layer, region, substrate or plate is placed on another element indicates not only a case where the element is placed directly on said another element but also a case where a further element is interposed between the element and said another element. On the contrary, an expression that an element is placed directly on another element indicates a case where no further element is interposed between the element and said another element.

First, as shown in FIG. 1, a nitride film 110 and a photoresist 115 are sequentially formed over a semiconductor substrate 100, the nitride film 110 is patterned using the photoresist 115 as a mask, and trenches 41 and 43 are formed by etching the semiconductor substrate 100 using the patterned nitride film 110 as a mask.

Next, the photoresist 115 is removed, and a high density plasma oxidation 120 is formed over the whole structure, including the semiconductor substrate 100, the nitride film 110, and trenches 41 and 43, as shown in FIG. 2.

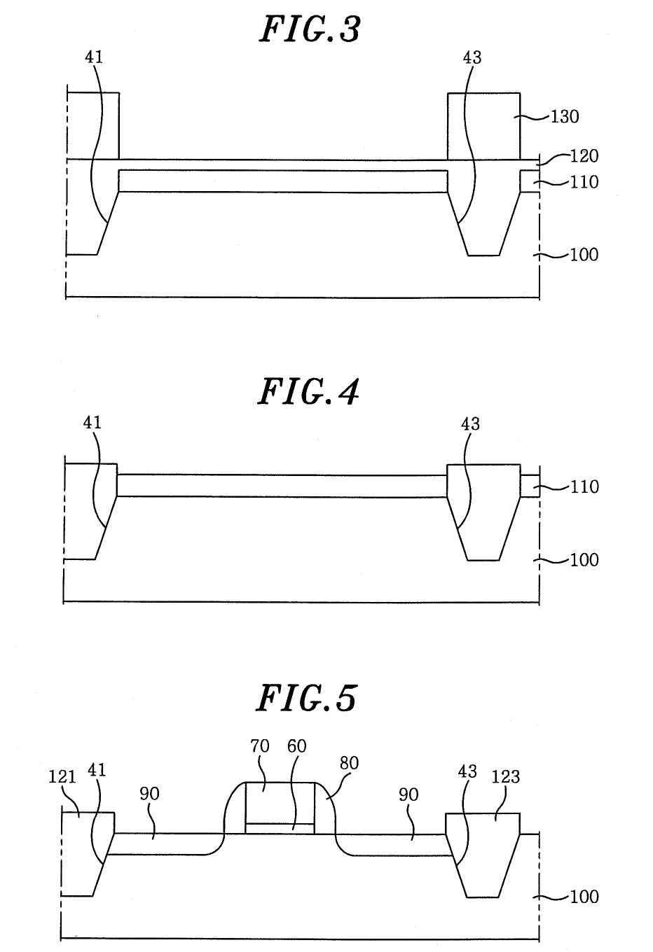

Then, a surface of the high density plasma oxidation 120 is planarized by performing a CMP process thereon as shown in FIG. 3. Subsequently, device isolation photoresist patterns 130 are formed over the trenches 41 and 43.

Next, as shown in FIG. 4, the high density plasma oxidation 120 existing over the nitride film 110 is completely removed through a wet etching process using the device isolation patterns 130 as a mask. The high density plasma oxidation 120 filling the trenches 41 and 43 are masked from the wet etching process by the device isolation patterns 130. The device isolation patterns 130 are then removed, and the nitride film 110 is completely removed. Accordingly, device isolation films 121 and 123 are formed.

As described above, once the high density plasma oxidation 120 over the nitride film 110 is completely removed, the nitride film 110 may be completely removed within a shorter timeframe than the process of removing a nitride film over which an oxidation film remains. Accordingly, the device isolation films 121 and 123 filling the trenches 41 and 43 of the semiconductor substrate 100 may be formed to have a height higher than that of the semiconductor substrate 100. Such device isolation films 121 and 123 function to thoroughly isolate a semiconductor device without limiting the critical dimension of a highly integrated semiconductor device. Leakage current can also be reduced, and the electrical characteristics and reliability of a semiconductor device can be enhanced, increasing the yield.

Next, a gate insulation film 60 and a gate electrode 70 are sequentially formed over the semiconductor substrate 100 in a device region between the device isolation films 121 and 123. A spacer 80 is formed over sides of the gate insulation film 60 and the gate electrode 70 as shown in FIG. 5. A highly doped junction region 90 is formed by implanting highly concentrated impurity ions onto the semiconductor substrate 100 exposed when using the gate electrode 70 and the spacer 80 as a mask.

When forming device isolation films with an STI method, the high density plasma oxidation layer over the nitride is planarized through a CMP process. A photoresist is formed over the high density plasma oxidation layer and over a region of trenches. The high density plasma oxidation layer over a nitride film is completely removed through a wet etching process using the photoresist as a mask, and the device isolation film is formed to have a height higher than that of the semiconductor substrate by removing the photoresist. Leakage currents of a semiconductor device can be prevented, thereby enhancing the electrical characteristics and reliability of the semiconductor device and increasing the yield of products.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a nitride film over a semiconductor substrate;
forming at least one trench in the semiconductor substrate;
forming an insulation film over the nitride film and in said at least one trench;
forming a mask pattern over said at least one trench; and
selectively removing the insulation film using the mask pattern as a mask.

2. The method of claim 1, further comprising forming a photoresist mask over the nitride film.

3. The method of claim 2, further comprising patterning the nitride film using the photoresist mask.

4. The method of claim 3, wherein said forming at least one trench comprises etching the semiconductor substrate using the nitride film as a mask.

5. The method of claim 1, further comprising planarizing the insulation film prior to forming the mask pattern.

6. The method of claim 5, wherein said planarizing is performed by chemical mechanical polishing.

7. The method of claim 5, wherein said planarizing leaves some of said insulation film over said nitride film.

8. The method of claim 1, further comprising removing the mask pattern.

9. The method of claim 8, further comprising removing the nitride film after said removing the mask pattern.

10. The method of claim 1, wherein said mask pattern is a photoresist.

11. The method of claim 1, wherein said selectively removing the insulation film is performed by wet etching.

12. The method of claim 1, wherein the insulation film is formed by high density plasma oxidation.
